(19) United States
(12) Patent Application Publication
(10) Pub. No.: US 2006/0193411 A1
(43) Pub. Date: Aug. 31, 2006

(54) Digital receiver method and apparatus using differential detection and equalization-based techniques

(76) Inventors: Shaohan J. Chou, Marlboro, NJ (US); Min Liang, Morganville, NJ (US); Steven C. Pinault, Allentown, PA (US); Jinguo Yu, Flemington, NJ (US)

Correspondence Address: RYAN, MASON & LEWIS, LLP, 1300 POST ROAD, SUITE 205, FAIRFIELD, CT, 06824, US

(21) Appl. No.: 11/068,511

(22) Filed: Feb. 28, 2005

(51) Int. Cl. H04B 1/10; H03H 7/30

(52) U.S. Cl. 375/348; 375/233

(57) ABSTRACT

Methods and apparatus are provided for processing a signal received on a channel. The intersymbol interference on the channel is initially evaluated and a detection method is selected from a plurality of available detection methods based on the intersymbol interference evaluation. For example, the plurality of available detection methods may include a differential detection technique and an equalization-based technique. The equalization technique may be, for example, a decision feedback equalization technique. The intersymbol interference evaluation may comprise, for example, a comparison of the signal to noise ratio at an output of a differential detector for at least a portion of a frame to a predefined threshold.

### FIELD OF THE INVENTION

The present invention relates generally to digital communication receivers, and more particularly, to techniques for addressing Intersymbol Interference in such digital communication receivers.

### BACKGROUND OF THE INVENTION

Differential detection techniques are used in many receivers, such as Personal Handy Phone System (PHS) digital receiver systems. The performance of such differential detection techniques, however, is limited by Intersymbol Interference (ISI) from the operating environment. For wireless channels that exhibit strong ISI, equalization based techniques, such as Decision Feedback Equalization (DFE) techniques, are used instead to improve system performance. For channels where there is only mild ISI, however, equalization is unnecessarily computationally intensive.

In fact, for those channels where the ISI is mild, the performance of the equalizer based receiver is not improved by the equalization technique (relative to a differential detection technique) and the performance might even be degraded. In addition, an equalization based receiver is generally more computationally intensive, usually requiring more MIPS (million instructions per second) for the more complex signal processing algorithms, and hence consumes more power (thereby shortening the battery life of the receiver).

While the above-described equalization and differential detection methods each perform in a satisfactory manner under appropriate conditions, a need exists for a detection method that demonstrates improved performance in any communication environment and is more resilient to ISI without unnecessarily consuming additional power.

### SUMMARY OF THE INVENTION

Generally, methods and apparatus are provided for processing a signal received on a channel. The intersymbol interference on the channel is initially evaluated and a detection method is selected from a plurality of available detection methods based on the intersymbol interference evaluation. For example, the plurality of available detection methods may include a differential detection technique and an equalization-based technique. The equalization technique may be, for example, a decision feedback equalization technique. The intersymbol interference evaluation may comprise, for example, a comparison of the signal to noise ratio at an output of a differential detector for at least a portion of a frame to a predefined threshold.

A more complete understanding of the present invention, as well as further features and advantages of the present invention, will be obtained by reference to the following detailed description and drawings.

### BRIEF DESCRIPTION OF THE DRAWINGS

FIG. 1 is a schematic block diagram of a receiver incorporating features of the present invention;

FIG. 2 is a schematic block diagram illustrating the differential detection subsystem of FIG. 1 in further detail;

FIG. 3 is a schematic block diagram illustrating the equalization subsystem of FIG. 1 in further detail; and

FIG. 4 is a flow chart describing an exemplary implementation of the methods of the present invention.

### DETAILED DESCRIPTION

The present invention recognizes that a differential detection based receiver can work very well for the channels where the ISI is mild, while an equalization based receiver system can attain high performance for the channels with serious ISI. According to one aspect of the present invention, a receiver selectively applies either the differential detection or equalization technique, based on ISI conditions. In this manner, the appropriate detection technique is applied based on channel conditions, without unnecessarily consuming battery power.

Generally, the present invention characterizes the operating environment into at least two categories based on an assessment of ISI. A first operating environment category is characterized by a mild ISI environment, where the differential detection based receiver performs well, thereby consuming less power. A second operating environment category is characterized by a more severe ISI environment, where the equalizer based receiver would provide improved performance (and warrants the increased battery consumption). The differential detection based receiver or the equalization based receiver is then selected based upon the operating environment that has been identified. The disclosed approach enables a receiver to take advantage of both the differential detection and equalization approaches, as needed, and hence can significantly improve and overcome the issue of jitter in PHS receiver system performance while reducing power consumption.

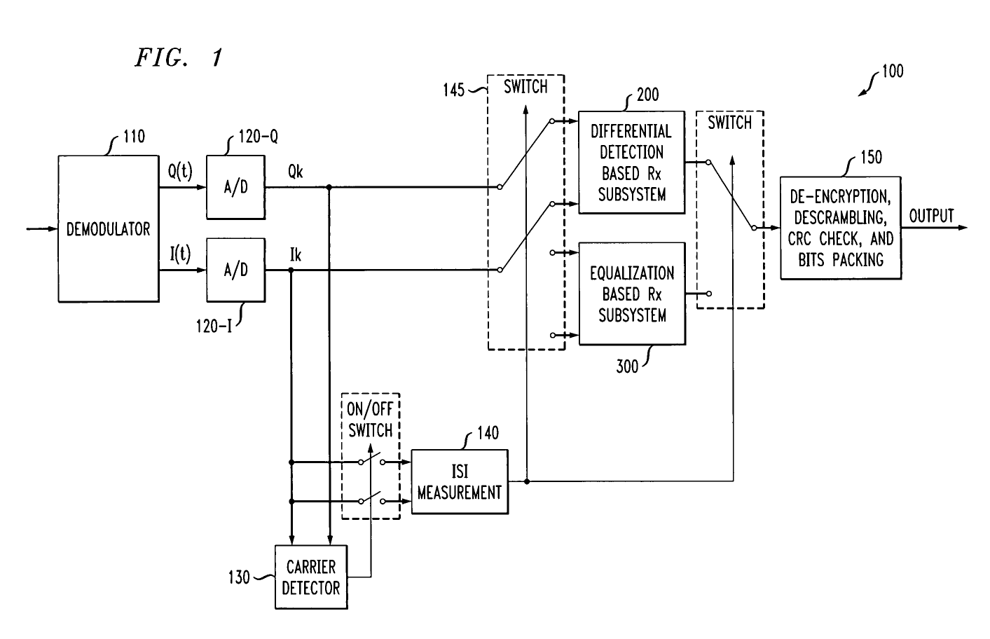

As previously indicated, the present invention first identifies the operating environment, based on the associated ISI. Thereafter, the differential detection based receiver or the equalization based receiver is enabled based upon the operating environment assessment. FIG. 1 is a schematic block diagram of a receiver 100 incorporating features of the present invention. As shown in FIG. 1, the received RF signal is first demodulated into I and Q baseband components by a demodulator 110. These I and Q signals are then each sampled by respective Analog to Digital Converters (ADC) 120-I, 120-Q with a sampling rate equal to twice the symbol rate. The resulting digitized baseband signals Iₖ, Qₖ are fed to a carrier detection measurement procedure 130 and an ISI measurement procedure 140, in a well-known manner.

For a more detailed discussion of the demodulation, sampling and carrier detection aspects of a conventional receiver, see, for example, Theodore Rappaport, Wireless Communications: Principles and Practice (2001), incorporated by reference herein.

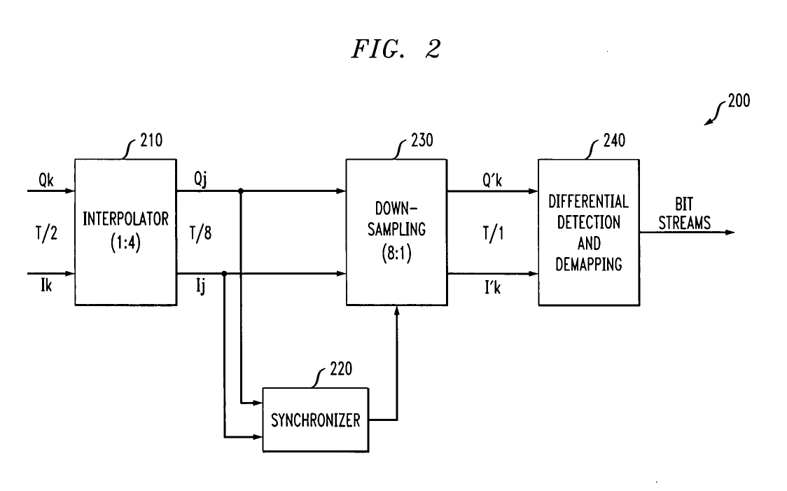

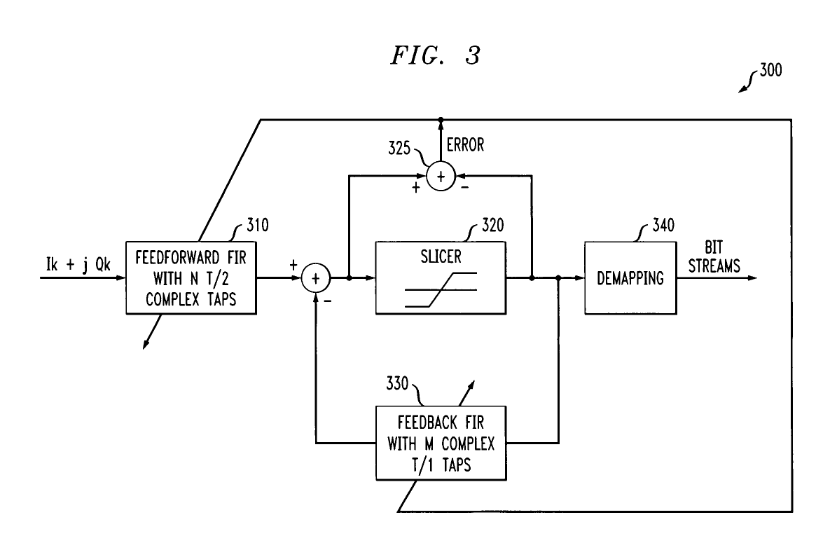

As shown in FIG. 1, the exemplary receiver 100 includes a switch 145 that selectively enables a differential detection based receiver subsystem 200, discussed further below in conjunction with FIG. 2, to further process the signals; or enables an equalization based receiver subsystem 300, discussed further below in conjunction with FIG. 3, for further processing. As previously indicated, the switch 145 enables the appropriate detection method 200, 300, based on the ISI measurement performed at stage 140, relative to a specified threshold. Following the selected detection method 200, 300, de-encryption, de-scrambling, CRC check and bit packing are performed at stage 150.

In one exemplary implementation, the ISI is evaluated at stage 140 by applying the differential detector 200 on some portion of the frame, such as the preamble and a unique word having predefined values. The signal to noise ratio (SNR) at the output of this detector 200 can be compared to a threshold to provide a reliable indicator of whether the differential detector 200 is adequate for detection. An SNR above the threshold indicates a low level of ISI, for which equalization is not required, while a SNR below the threshold indicates a high level of ISI for which equalization will give a significant improvement in performance, justifying the extra signal processing power.

FIG. 2 is a schematic block diagram illustrating the differential detection subsystem 200 of FIG. 1 in further detail. As shown in FIG. 2, the input signals are further over sampled by a factor of 4 via interpolation at stage 210 and the resulting samples are then applied to a synchronizer 220 where the optimal symbol rate sampling phase is found (in order to synchronize the received frame). The signals are then down sampled at stage 230 back to the symbol rate at this optimal phase. Thereafter, differential detection and de-mapping are performed at state 240 to generate the bit streams which will be further processed with de-encryption (if necessary), de-scrambling, CRC and bit packing (stage 150, FIG. 1) to get final results.

For a more detailed discussion of suitable differential detection techniques, see, for example, Theodore Rappaport, Wireless Communications: Principles and Practice, Ch. 6 (2001), or U.S. patent application Ser. No. ______, filed contemporaneously herewith, entitled “Method and Apparatus for Compensation of Doppler Induced Carrier Frequency Offset in a Digital Receiver System,” incorporated by reference herein.

It is noted that the synchronizer 220 is a correlation calculator for each phase of the symbol, plus a trace-back check to find the real optimal phase information. The reason for use of the trace-back check is that although the point of maximal value of the correlation among all phases is an effective estimate of the optimal phase, this estimate can have error due to the impairments of the operating environment. In order to get the refined estimate of the optimal phase, the trace-back check is carried out on the neighbors of the maximal point.

FIG. 3 is a schematic block diagram illustrating the equalization subsystem 300 of FIG. 1 in further detail. The equalization subsystem 300 may be implemented as a Decision Feedback Equalizer or a linear feedforward equalizer.

Generally, as shown in FIG. 3, the digitized baseband signals Iₖ, Qₖ are fed to a feed-forward FIR 310. The N complex coefficients of the feed-forward FIR are initialized by a central-tap algorithm which is based on the information provided by the carrier detector 130 of FIG. 1, while the M complex coefficients of a feed-back FIR 330 are set to values of zero. The learning algorithm for the exemplary DFE 300 is least mean square (LMS)-based using a block-multiple-epoch adaptive update approach.

It is noted that for rapid training on a short ideal reference sequence for PHS, it is important to do the multiple updates in a block, rather than on a symbol by symbol basis. The ideal reference training epoch is comprised of the corresponding preamble (PR) and unique word (UW) which are specified in the PHS STD-28 standard (Version 3.3). It is further noted that even though PR is not normally used for training, being a periodic sequence, a short portion of PR can be used effectively to increase the training in the case of a very short training sequence, as found in PHS. After the ideal reference training procedure is completed, the DFE 300 enters the data-directed training phase and the output of the slicer 320 is fed to the de-mapping module 340 to get the bit streams which will be processed by the following modules of de-encryption, de-scrambling, CRC check and bit packing (stage 150, FIG. 1).

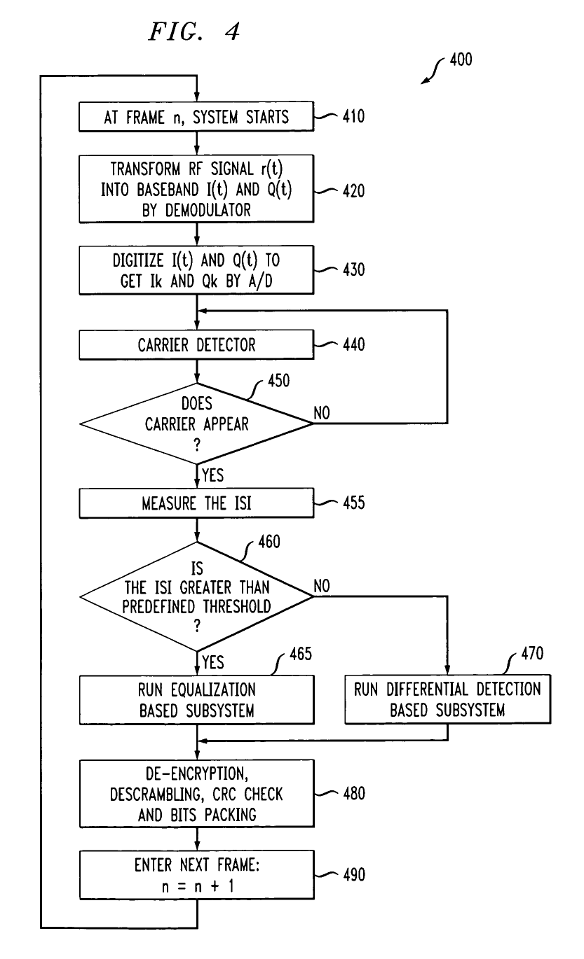

FIG. 4 is a flow chart describing an exemplary implementation of the methods of the present invention. As shown in FIG. 4, the process 400 is initiated during step 410 upon receipt of a frame, n. Thereafter, the received RF signal r(t) is transformed during step 420 into baseband I(t) and Q(t) signals by the demodulator 110. The I and Q signals are then each sampled by respective Analog to Digital Converters (ADC) 120-I, 120-Q during step 430 to obtain digitized baseband signals Iₖ, Qₖ.

Carrier detection is performed at step 440 and a test is performed during step 450 to determine if the carrier frequency has appeared. If it is determined during step 450 that the carrier frequency has not appeared, then program control returns to step 440.

Once it is determined during step 450 that the carrier frequency has appeared, then the ISI is measured during step 455 (at stage 140 of FIG. 1). A test is performed during step 460 to determine if the measured ISI is greater than a predefined threshold. If it is determined during step 460 that the measured ISI is greater than a predefined threshold, then the equalization based subsystem 300 is selected for detection during step 465. If, however, it is determined during step 460 that the measured ISI is not greater than the predefined threshold, then the differential detection based subsystem 200 is selected for detection during step 470.

Following detection during step 465 or 470, de-encryption, de-scrambling, CRC check and bit packing are performed during step 480 (using stage 150, FIG. 1), before the frame is incremented during step 490, for processing of the next frame.

In this manner, the present invention improves performance and reduced power consumption of a PHS receiver system, or another receiver, by efficiently selecting an appropriate detection method based on channel conditions. In addition, the present invention eliminates the jitter that occurs with current PHS handset receiver implementations.

It is to be understood that the embodiments and variations shown and described herein are merely illustrative of the principles of this invention and that various modifications may be implemented by those skilled in the art without departing from the scope and spirit of the invention.

We claim:

1. A method for processing a signal received on a channel, comprising:
evaluating intersymbol interference on said channel; and
selecting a detection method from a plurality of available detection methods based on said intersymbol interference evaluation.

2. The method of claim 1, wherein said plurality of available detection methods includes a differential detection technique.

3. The method of claim 1, wherein said plurality of available detection methods includes an equalization technique.

4. The method of claim 3, wherein said equalization technique is a decision feedback equalization technique.

5. The method of claim 1, wherein said evaluating step further comprises the step of comparing a signal to noise ratio at an output of a differential detector for at least a portion of a frame to a predefined threshold.

6. The method of claim 5, wherein said at least a portion of a frame comprises a preamble and at least one unique word having predefined values.

7. A wireless receiver for processing a signal received on a channel, comprising:
an intersymbol interference measurement stage for evaluating intersymbol interference on said channel; and
a detector that applies one of a plurality of available detection methods to said received signal based on said intersymbol interference evaluation.

8. The wireless receiver of claim 7, wherein said plurality of available detection methods includes a differential detection technique.

9. The wireless receiver of claim 7, wherein said plurality of available detection methods includes an equalization technique.

10. The wireless receiver of claim 9, wherein said equalization technique is a decision feedback equalization technique.

11. The wireless receiver of claim 7, wherein said intersymbol interference measurement stage compares a signal to noise ratio at an output of a differential detector for at least a portion of a frame to a predefined threshold.

12. The wireless receiver of claim 11, wherein said at least a portion of a frame comprises a preamble and at least one unique word having predefined values.

13. A wireless receiver for processing a signal received on a channel, comprising:
a memory; and
at least one processor, coupled to the memory, operative to:
obtain an intersymbol interference estimate for said channel; and
apply one of a plurality of available detection methods to said received signal based on said intersymbol interference estimate.

14. The wireless receiver of claim 13, wherein said plurality of available detection methods includes a differential detection technique.

15. The wireless receiver of claim 13, wherein said plurality of available detection methods includes an equalization technique.

16. The wireless receiver of claim 15, wherein said equalization technique is a decision feedback equalization technique.

17. The wireless receiver of claim 13, wherein said intersymbol interference estimate is a signal to noise ratio at an output of a differential detector for at least a portion of a frame.

18. The wireless receiver of claim 17, wherein said at least a portion of a frame comprises a preamble and at least one unique word having predefined values.
